(19) United States
(12) Patent Application Publication
(10) Pub. No.: US 2024/0260476 A1
(43) Pub. Date: Aug. 1, 2024

(54) PIEZOELECTRIC FILM AND LAMINATED PIEZOELECTRIC ELEMENT

(71) Applicant: FUJIFILM Corporation, Tokyo (JP)

(72) Inventor: Tetsu MIYOSHI, Minamiashigara-shi (JP)

(73) Assignee: FUJIFILM Corporation, Tokyo (JP)

(21) Appl. No.: 18/595,568

(22) Filed: Mar. 5, 2024

Related U.S. Application Data
(63) Continuation of application No. PCT/JP2022/034746, filed on Sep. 16, 2022.

(30) Foreign Application Priority Data
Sep. 28, 2021 (JP) 2021-157792

(51) Int. Cl. H10N 30/50; H10N 30/072; H10N 30/85; H10N 30/88

(52) U.S. Cl. CPC H10N 30/50; H10N 30/072; H10N 30/85; H10N 30/883

(57) ABSTRACT

An object of the present invention is to provide a piezoelectric film and a laminated piezoelectric element, in which, in a piezoelectric film including electrode layers and protective layers on both surfaces of a piezoelectric layer containing piezoelectric particles in a matrix containing a polymer material, changes in mechanical properties and electrical properties due to a humidity of an external environment can be reduced. The piezoelectric film includes a piezoelectric layer containing piezoelectric particles in a matrix containing a polymer material, electrode layers provided on both surfaces of the piezoelectric layer, and a protective layer provided on a surface of the electrode layer opposite to the piezoelectric layer, in which the protective layer has a resin substrate and at least one inorganic layer provided on the resin substrate, and a water vapor transmission rate of the piezoelectric film is 1×10⁻⁴ g/(m²×day) or less.

### CROSS-REFERENCE TO RELATED APPLICATIONS

This application is a Continuation of PCT International Application No. PCT/JP2022/034746 filed on Sep. 16, 2022, which claims priority under 35 U.S.C. § 119(a) to Japanese Patent Application No. 2021-157792 filed on Sep. 28, 2021. The above applications are hereby expressly incorporated by reference, in their entirety, into the present application.

### BACKGROUND OF THE INVENTION

### 1. Field of the Invention

The present invention relates to a piezoelectric film used as an electroacoustic conversion film or the like, and a laminated piezoelectric element obtained by laminating the piezoelectric films.

### 2. Description of the Related Art

Flexible displays, such as an organic EL display, which include a flexible substrate such as plastic have been developed.

In a case where such a flexible display is used as an image display device also serving as a sound generator which reproduces a voice together with an image, such as a television receiver, a speaker which is an acoustic device for generating the voice is required.

Here, examples of a typical shape of the speaker in the related art include a funnel-like so-called cone shape and a spherical dome shape. However, in a case where such a speaker is intended to be incorporated in the above-described flexible display, there is a concern that lightness and flexibility, which are advantages of the flexible display, are impaired. In addition, in a case where the speaker is attached externally, since the speaker is troublesome to carry and difficult to install on a curved wall, there is a concern that an appearance is impaired.

Meanwhile, a piezoelectric film with flexibility has been suggested as a speaker which can be integrated with the flexible display without impairing the lightness and the flexibility.

For example, WO2013/047875A discloses an electroacoustic conversion film (piezoelectric film) including a polymer-based piezoelectric composite material (piezoelectric layer) obtained by dispersing piezoelectric particles in a viscoelastic matrix composed of a polymer material having viscoelasticity at normal temperature, thin film electrodes (electrode layers) provided on both surfaces of the polymer-based piezoelectric composite material, and a protective layer provided on a surface of the thin film electrode.

### SUMMARY OF THE INVENTION

WO2013/047875A discloses that, by dispersing the piezoelectric particles in the viscoelastic matrix composed of a polymer material having viscoelasticity at normal temperature, the maximal value of an internal loss according to a dynamic viscoelasticity test at a frequency 1 Hz is 0.1 or more at the normal temperature (0° C. to 50° C.), so that very excellent flexibility is exhibited with respect to a slow deformation from the outside, and as a result, it is possible to be mounted on a flexible device. In addition, in WO2013/047875A, in order to achieve excellent flexibility and piezoelectric characteristics, it is disclosed that the thin film electrode layer and the protective layer are preferably as thin as possible, the protective layer is preferably a resin film of a polyethylene terephthalate, a polypropylene, or the like having a thickness of several micrometers, the thin film electrode layer is preferably a copper layer, an aluminum layer, or the like formed in a vapor phase using the protective layer as a base material by sputtering, vapor deposition, and the like.

Here, according to studies by the present inventor, it has been found that the piezoelectric film in which the polymer-based piezoelectric composite material including, as the matrix, the polymer material having viscoelasticity at normal temperature is used as the piezoelectric layer has a problem that mechanical properties such as an elastic modulus and electrical properties such as an electrostatic capacitance are changed depending on environments. The present inventor has further studied on this point and found that the mechanical properties and the electrical properties are changed by an external environment, particularly, a humidity.

An object of the present invention is to solve such problems of the related art, and to provide a piezoelectric film and a laminated piezoelectric element, in which, in a piezoelectric film including electrode layers and protective layers on both surfaces of a piezoelectric layer containing piezoelectric particles in a matrix containing a polymer material, changes in mechanical properties and electrical properties due to an external environment can be reduced.

In order to achieve the above-described objects, the present invention has the following configurations.

[1] A piezoelectric film comprising:
a piezoelectric layer containing piezoelectric particles in a matrix containing a polymer material;
electrode layers provided on both surfaces of the piezoelectric layer; and
a protective layer provided on a surface of the electrode layer opposite to the piezoelectric layer,
in which the protective layer has a resin substrate and at least one inorganic layer provided on the resin substrate, and
a water vapor transmission rate of the piezoelectric film is 1×10⁻⁴ g/(m²×day) or less.

[2] The piezoelectric film according to [1],
in which a water vapor transmission rate of the protective layer is 1×10⁻⁴ g/(m²×day) or less.

[3] The piezoelectric film according to [1] or [2],
in which the inorganic layer is disposed between the piezoelectric layer and the resin substrate.

[4] The piezoelectric film according to any one of [1] to [3],
in which the inorganic layer has an amorphous structure.

[5] The piezoelectric film according to any one of [1] to [4],
in which the inorganic layer is an insulator.

[6] The piezoelectric film according to any one of [1] to [5],
in which the inorganic layer consists of silicon nitride.

[7] The piezoelectric film according to any one of [1] to [6],
in which a thickness of the inorganic layer is 100 nm or less.

[8] A laminated piezoelectric element obtained by laminating a plurality of layers of the piezoelectric films according to any one of [1] to [7].

[9] The laminated piezoelectric element according to [8],
in which the plurality of layers of the piezoelectric films are laminated by folding the piezoelectric film one or more times.

According to the present invention, it is possible to provide a piezoelectric film and a laminated piezoelectric element, in which, in a piezoelectric film including electrode layers and protective layers on both surfaces of a piezoelectric layer containing piezoelectric particles in a matrix containing a polymer material, changes in mechanical properties and electrical properties due to a humidity of an external environment can be reduced.

### BRIEF DESCRIPTION OF THE DRAWINGS

FIG. 1 is a conceptual view showing an example of a piezoelectric film according to an embodiment of the present invention.

FIG. 2 is a conceptual view showing another example of the piezoelectric film according to the embodiment of the present invention.

FIG. 3 is a conceptual view for describing an example of a production method of the piezoelectric film.

FIG. 4 is a conceptual view for describing an example of the production method of the piezoelectric film.

FIG. 5 is a conceptual view for describing an example of the production method of the piezoelectric film.

FIG. 6 is a conceptual view for describing an example of the production method of the piezoelectric film.

FIG. 7 is a conceptual view showing an example of a laminated piezoelectric element according to an embodiment of the present invention.

FIG. 8 is a conceptual view showing another example of the laminated piezoelectric element according to the embodiment of the present invention.

### DESCRIPTION OF THE PREFERRED EMBODIMENTS

Hereinafter, the piezoelectric film and the laminated piezoelectric element according to the embodiment of the present invention will be described in detail based on suitable examples shown in the accompanying drawings.

Although configuration requirements to be described below are described based on representative embodiments of the present invention, the present invention is not limited to the embodiments.

Any numerical range expressed using “to” in the present specification refers to a range including the numerical values before and after the “to” as a lower limit value and an upper limit value, respectively.

In addition, the drawings shown below are conceptual views for describing the present invention, and the thickness of each layer, the size of the piezoelectric particles, the size of the constituent members, and the like are different from the actual values.

### [Piezoelectric Film]

The piezoelectric film according to the embodiment of the present invention is a piezoelectric film including a piezoelectric layer containing piezoelectric particles in a matrix containing a polymer material, electrode layers provided on both surfaces of the piezoelectric layer, and a protective layer provided on a surface of the electrode layer opposite to the piezoelectric layer, in which the protective layer has a resin substrate and at least one inorganic layer provided on the resin substrate, and a water vapor transmission rate of the piezoelectric film is 1×10⁴ g/(m²×day) or less.

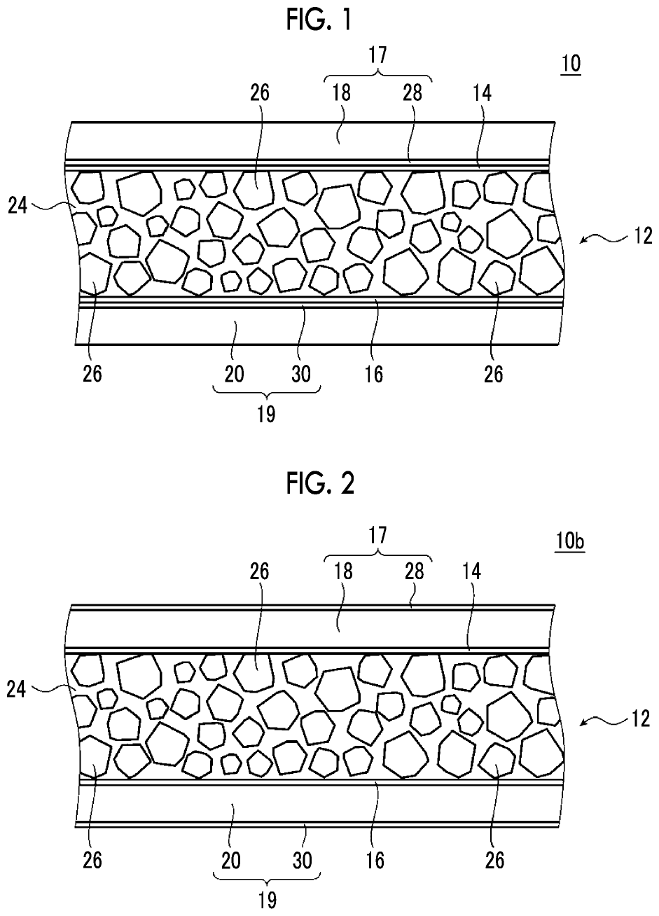

FIG. 1 conceptually shows an example of the piezoelectric film according to the embodiment of the present invention.

As shown in FIG. 1, a piezoelectric film 10 includes a piezoelectric layer 12, a first electrode layer 14 laminated on one surface of the piezoelectric layer 12, a first protective layer 17 laminated on a surface of the first electrode layer 14, a second electrode layer 16 laminated on the other surface of the piezoelectric layer 12, and a second protective layer 19 laminated on a surface of the second electrode layer 16. That is, the piezoelectric film 10 has a configuration in which such a piezoelectric layer 12 is sandwiched between the electrode layers and the protective layer is laminated on a surface of the electrode layer, which is not in contact with the piezoelectric layer.

In the piezoelectric film 10, the piezoelectric layer 12 contains piezoelectric particles 26 in a matrix 24 containing a polymer material, as conceptually shown in FIG. 1. As will be described later, the piezoelectric film 10, that is, the piezoelectric layer 12 is polarized in a thickness direction as a preferred embodiment.

Here, in the piezoelectric film 10 according to the embodiment of the present invention, the first protective layer 17 has a first resin substrate 18 and a first inorganic layer 28 provided on the first resin substrate 18, and the second protective layer 19 has a second resin substrate 20 and a second inorganic layer 30 provided on the second resin substrate 20.

The first inorganic layer 28 and the second inorganic layer 30 act as a layer which imparts water vapor barrier properties. In the piezoelectric film 10 according to the embodiment of the present invention, since the protective layer has the inorganic layer, the water vapor transmission rate is set to 1×10⁻⁴ g/(m²×day) or less.

In the example shown in FIG. 1, the first inorganic layer 28 is disposed between the piezoelectric layer 12 and the first resin substrate 18, and the second inorganic layer 30 is disposed between the piezoelectric layer 12 and the second resin substrate 20. That is, the piezoelectric film 10 includes the first resin substrate 18, the first inorganic layer 28, the first electrode layer 14, the piezoelectric layer 12, the second electrode layer 16, the second inorganic layer 30, and the second resin substrate 20 in this order.

In the present invention, the terms “first” and “second” in the first electrode layer 14 and the second electrode layer 16, the first resin substrate 18 and the second resin substrate 20, the first inorganic layer 28 and the second inorganic layer 30, and the first protective layer 17 and the second protective layer 19 are used to distinguish two similar members of the piezoelectric film 10 for convenience. That is, the terms “first” and “second” of the constituent elements of the piezoelectric film 10 have no technical meaning. Therefore, a coating material for forming the piezoelectric layer 12, which will be described later, may be applied to any of the first electrode layer 14 or the second electrode layer 16.

In the following description, in a case where it is not necessary to distinguish between the “first” and “second”, the first and second electrode layers, the first and second resin substrates, the first and second inorganic layers, and the first and second protective layers are also simply referred to as an electrode layer, a resin substrate, an inorganic layer, and a protective layer, respectively.

As described above, it has been found that the piezoelectric film in which the polymer-based piezoelectric composite material including, as the matrix, the polymer material is used as the piezoelectric layer has a problem that mechanical properties such as an elastic modulus and electrical properties such as an electrostatic capacitance are changed depending on environments. The present inventor has further studied on this point and found that the mechanical properties and the electrical properties of the piezoelectric film are changed by an external environment (humidity).

More specifically, the polymer material having viscoelasticity at normal temperature has a glass transition point near the normal temperature. In general, since a relative permittivity of the polymer material is maximized near the glass transition point, in a case where the glass transition point fluctuates up and down due to some factor, the mechanical properties (clastic modulus and the like) and the electrical properties (electrostatic capacitance and the like) of the piezoelectric film are changed. In general, it has been known that the piezoelectric characteristics are improved as the relative permittivity of the matrix in the polymer-based piezoelectric composite material increases because a strength of electric field applied to the piezoelectric particles increases. Therefore, the piezoelectric characteristics can be improved by using a cyanoresin (a general term for a polymer having a cyanoethyl group in a side chain) which is a material having a particularly large relative permittivity among polymer materials. However, in process of synthesizing the cyanoresin, it is difficult to substitute the side chain with the cyanocthyl group by 100%, and it has been known that approximately 3% to 30% of the side chain is to be a hydroxyl group (OH). Since the hydroxyl group has hydrophilicity, water molecules are adsorbed or desorbed depending on the external environment (humidity). Accordingly, the glass transition point of the polymer material fluctuates up and down. In addition, since the cyanoethyl group itself also has a slight hydrophilicity, even in a case where the substitution rate is increased to 100%, it is impossible to completely eliminate the fluctuation in glass transition point due to the external environment.

Here, both surfaces of the piezoelectric layer are covered with electrode layers and protective layers, and the piezoelectric layer is sandwiched therebetween. In general, a thin film electrode layer formed by a film formation with sputtering or vapor deposition has a columnar tissue structure in which a crystal grain boundary is formed in a film thickness direction. In such an electrode layer, since water molecules diffuse along the crystal grain boundary, the water vapor barrier properties are low. In addition, it has been known that the protective layer consisting of a resin film also has low water vapor barrier properties. Therefore, even in a case where the electrode layer and the protective layer cover the piezoelectric layer, it is not possible to suppress the infiltration of water molecules into the piezoelectric layer, and the mechanical properties and the electrical properties of the piezoelectric film are changed by the external environment.

On the other hand, in the piezoelectric film according to the embodiment of the present invention, by adopting the configuration in which the protective layer has the resin substrate and at least one inorganic layer provided on the resin substrate, and the water vapor transmission rate of the piezoelectric film is 1×10⁻⁴ g/(m²×day) or less, that is, by adopting the configuration in which the protective layer has the inorganic layer having high water vapor barrier properties, it is possible to suppress the infiltration or release of the water molecules into or from the piezoelectric layer due to the external environment (humidity), and it is possible to suppress the fluctuation of the glass transition point of the polymer material due to the external environment. Therefore, it is possible to reduce the change in mechanical properties and electrical properties of the piezoelectric film due to the external environment.

Here, a water vapor transmission rate of the protective layer is preferably 1×10⁴ g/(m²×day) or less, more preferably 5×10⁵ g/(m²×day) or less, and still more preferably 1×10⁻⁵ g/(m²×day) or less.

In addition, from the viewpoint of reducing the changes in mechanical properties and electrical properties of the piezoelectric film due to the external environment, the water vapor transmission rate of the piezoelectric film is more preferably 5×10⁻⁵ g/(m²×day) or less and still more preferably 1×10⁵ g/(m²×day) or less.

The water vapor transmission rates of the piezoelectric film and the protective layer can be measured by a calcium corrosion method (method described in JP2005-283561A).

Here, in the example shown in FIG. 1, the inorganic layer is disposed between the piezoelectric layer and the resin substrate, but the present invention is not limited thereto.

FIG. 2 shows another example of the piezoelectric film according to the embodiment of the present invention.

A piezoelectric film 10b shown in FIG. 2 has a first inorganic layer 28, a first resin substrate 18, a first electrode layer 14, a piezoelectric layer 12, a second electrode layer 16, a second resin substrate 20, and a second inorganic layer 30 in this order. That is, in the piezoelectric film 10b, the inorganic layer is disposed on a surface of the resin substrate opposite to the electrode layer.

In this way, the inorganic layer may be disposed on the surface of the resin substrate opposite to the electrode layer. In a case where the inorganic layer is disposed on the surface of the resin substrate opposite to the electrode layer, a path through which the water molecules enter the piezoelectric layer from an end part of the resin substrate is generated. Therefore, in the configuration in which the inorganic layer is disposed between the resin substrate and the piezoelectric layer, the water molecules penetrating from the end part of the resin substrate can also be shielded, which is preferable.

Hereinafter, constituent elements of the piezoelectric film according to the embodiment of the present invention will be described in detail.

As described above, in the piezoelectric film 10 according to the embodiment of the present invention, the piezoelectric layer 12 is formed by dispersing the piezoelectric particles 26 in the matrix 24 containing a polymer material. That is, the piezoelectric layer 12 is a polymer-based piezoelectric composite material.

Here, it is preferable that the polymer-based piezoelectric composite material (piezoelectric layer 12) satisfies the following requirements. In the present invention, normal temperature is in a range of 0° C. to 50° C.

### (i) Flexibility

For example, in a case of being gripped in a state of being loosely bent with a sense of document such as a newspaper and a magazine as a portable device, the polymer-based piezoelectric composite material is continuously subjected to large bending deformation from the outside at a comparatively slow vibration of less than or equal to a few Hz. At this time, in a case where the polymer-based piezoelectric composite material is rigid, large bending stress is generated to that extent, and a crack is generated at an interface between the polymer matrix and the piezoelectric particles, which may lead to breakage. Accordingly, the polymer-based piezoelectric composite material is required to have suitable flexibility. In addition, in a case where strain energy is diffused into the outside as heat, the stress can be relaxed. Therefore, the polymer-based piezoelectric composite material is required to have a suitably large loss tangent.

### (ii) Acoustic Quality

In a speaker, the piezoelectric particles vibrate at a frequency of an audio band of 20 Hz to 20 kHz, and vibration energy causes the entire vibration plate (polymer-based piezoelectric composite material) to vibrate integrally so that sound is reproduced. Therefore, in order to increase transmission efficiency of the vibration energy, the polymer-based piezoelectric composite material is required to have appropriate rigidity. In addition, in a case where frequency characteristics of the speaker are smooth, an amount of a change in acoustic quality decreases in a case where the lowest resonance frequency f₀ is changed in association with a change in curvature of the speaker. Therefore, the polymer-based piezoelectric composite material is required to have a suitably large loss tangent.

It has been known that the lowest resonance frequency f₀ of the vibration plate for a speaker is represented by the following expression. Here, s represents the stiffness of the vibration system, and m represents the mass.

$$Lowest resonance frequency : {f}_{0} = \frac{1}{2 π} \sqrt{\frac{s}{m}}$$

Here, as a degree of bending of the piezoelectric film, that is, a curvature radius of a bending portion increases, a mechanical stiffness s decreases, and thus the lowest resonance frequency f₀ decreases. That is, acoustic quality (volume and frequency characteristics) of the speaker changes depending on the curvature radius of the piezoelectric film.

That is, the flexible polymer-based piezoelectric composite material used as an electroacoustic conversion film is required to exhibit a behavior of being rigid with respect to a vibration of 20 Hz to 20 kHz and being flexible with respect to a vibration of less than or equal to a few Hz. In addition, the loss tangent of the polymer-based piezoelectric composite material is required to be suitably large with respect to the vibration of all frequencies of 20 kHz or less.

In general, a polymer solid has a viscoelasticity relaxing mechanism, and a molecular movement with a large scale is observed as a decrease (relaxation) in a storage elastic modulus (Young's modulus) or a maximal value (absorption) in a loss elastic modulus along with an increase in temperature or a decrease in frequency. Among these, the relaxation due to a microbrown movement of a molecular chain in an amorphous region is referred to as main dispersion, and an extremely large relaxing phenomenon is observed. A temperature at which this main dispersion occurs is a glass transition point (Tg), and the viscoelasticity relaxing mechanism is most remarkably observed.

In the polymer-based piezoelectric composite material (piezoelectric layer 12), the polymer-based piezoelectric composite material exhibiting a behavior of being rigid with respect to the vibration of 20 Hz to 20 KHz and being flexible with respect to the slow vibration of less than or equal to a few Hz is achieved by using, as a matrix, a polymer material having a glass transition point at normal temperature, that is, a polymer material having viscoelasticity at normal temperature. In particular, from the viewpoint that such a behavior is suitably exhibited, it is preferable that a polymer material in which the glass transition point at a frequency of 1 Hz is at normal temperature, that is, in a range of 0° C. to 50° C. is used for a matrix of the polymer-based piezoelectric composite material.

As the polymer material having a viscoelasticity at normal temperature, various known materials can be used. It is preferable that a polymer material in which the maximal value of a loss tangent Tan δ at a frequency of 1 Hz according to a dynamic viscoelasticity test at normal temperature, that is, in a range of 0° C. to 50° C. is 0.5 or more is used as the polymer material.

In this manner, in a case where the polymer-based piezoelectric composite material is slowly bent due to an external force, stress concentration on the interface between the polymer matrix and the piezoelectric particles at the maximum bending moment portion is relaxed, and thus high flexibility can be expected.

In the polymer material having a viscoelasticity at normal temperature, it is preferable that a storage elastic modulus (E′) at a frequency of 1 Hz according to the dynamic viscoelasticity measurement is 100 MPa or more at 0° C. and 10 MPa or less at 50° C.

In this manner, a bending moment generated in a case where the polymer-based piezoelectric composite material is slowly bent due to the external force can be reduced, and at the same time, the polymer-based piezoelectric composite material can exhibit a behavior of being rigid with respect to an acoustic vibration of 20 Hz to 20 KHz.

In addition, it is more suitable that a relative permittivity of the polymer material having a viscoelasticity at normal temperature is 10 or more at 25° C. Accordingly, in a case where a voltage is applied to the polymer-based piezoelectric composite material, a higher electric field is applied to the piezoelectric particles in the polymer matrix, and thus a large deformation amount can be expected.

However, in consideration of ensuring favorable moisture resistance and the like, it is suitable that the relative permittivity of the polymer material is 10 or less at 25° C.

Examples of the polymer material having a viscoelasticity at normal temperature and satisfying such conditions include cyanoethylated polyvinyl alcohol (cyanoethylated PVA), polyvinyl acetate, poly(vinylidene chloride-co-acrylonitrile), a polystyrene-vinyl polyisoprene block copolymer, polyvinyl methyl ketone, and polybutyl methacrylate. In addition, as these polymer materials, a commercially available product such as Hybrar 5127 (manufactured by Kuraray Co., Ltd.) can also be suitably used. Among these, as the polymer material, a material having a cyanoethyl group is preferably used, and cyanoethylated PVA is particularly preferably used.

In the matrix 24, these polymer materials may be used alone or in combination (mixture) of a plurality of kinds thereof.

A polymer material having no viscoelasticity at normal temperature may also be added to the matrix 24 as necessary, in addition to the polymer material having a viscoelasticity at normal temperature.

That is, for the purpose of adjusting dielectric characteristics, mechanical characteristics, and the like, other dielectric polymer materials may be added to the matrix 24 as necessary, in addition to the polymer material having viscoelasticity at normal temperature, such as cyanoethylated PVA.

Examples of the dielectric polymer material which can be added thereto include fluorine-based polymers such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, and a polyvinylidene fluoride-tetrafluoroethylene copolymer; polymers having a cyano group or a cyanoethyl group, such as a vinylidene cyanide-vinyl acetate copolymer, cyanoethyl cellulose, cyanoethyl hydroxysaccharose, cyanocthyl hydroxycellulose, cyanocthyl hydroxypullulan, cyanoethyl methacrylate, cyanoethyl acrylate, cyanoethyl hydroxyethyl cellulose, cyanoethyl amylose, cyanoethyl hydroxypropyl cellulose, cyanoethyl dihydroxypropyl cellulose, cyanoethyl hydroxypropyl amylose, cyanoethyl polyacrylamide, cyanoethyl polyacrylate, cyanoethyl pullulan, cyanoethyl polyhydroxymethylene, cyanoethyl glycidol pullulan, cyanoethyl saccharose, and cyanoethyl sorbitol; and synthetic rubber such as nitrile rubber and chloroprene rubber.

Among these, a polymer material having a cyanoethyl group is suitably used.

In addition, the dielectric polymer added to the matrix 24 of the piezoelectric layer 12 in addition to the material having a viscoelasticity at normal temperature, such as cyanoethylated PVA, is not limited to one dielectric polymer, and a plurality of kinds of dielectric polymers may be added.

In addition, for the purpose of controlling the glass transition point Tg, a thermoplastic resin such as a vinyl chloride resin, polyethylene, polystyrene, a methacrylic resin, polybutene, and isobutylene, and a thermosetting resin such as a phenol resin, a urea resin, a melamine resin, an alkyd resin, and mica may be added to the matrix 24 in addition to the dielectric polymer material.

Furthermore, for the purpose of improving pressure sensitive adhesiveness, a viscosity imparting agent such as rosin ester, rosin, terpene, terpene phenol, and a petroleum resin may be added.

In the matrix 24 of the piezoelectric layer 12, an addition amount of materials to be added, other than the polymer material having viscoelasticity at normal temperature, such as cyanoethylated PVA, is not particularly limited, but is preferably set to 30% by mass or less in terms of the proportion of the materials in the matrix 24.

In this manner, characteristics of the polymer material to be added can be exhibited without impairing the viscoelasticity relaxing mechanism in the matrix 24, so that preferred results such as an increase in permittivity, improvement of heat resistance, and improvement of adhesiveness between the piezoelectric particles 26 and the electrode layer can be obtained.

In the piezoelectric film 10 according to the embodiment of the present invention, the piezoelectric layer 12 contains the piezoelectric particles 26 in such a matrix 24. Specifically, the piezoelectric layer 12 is a polymer-based piezoelectric composite material formed by dispersing the piezoelectric particles 26 in the matrix 24.

The piezoelectric particles 26 consist of ceramic particles having a perovskite type or wurtzite type crystal structure.

Examples of the ceramic particles constituting the piezoelectric particles 26 include lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFe₃).

Only one of these piezoelectric particles 26 may be used, or a plurality of kinds thereof may be used in combination (mixture).

A particle diameter of the piezoelectric particles 26 is not limited, and may be appropriately selected according to the size, applications, and the like of the piezoelectric film 10.

The particle diameter of the piezoelectric particles 26 is preferably 1 to 10 μm. By setting the particle diameter of the piezoelectric particles 26 to be within the above-described range, preferred results in terms of achieving both excellent piezoelectric characteristics and flexibility of the piezoelectric film 10 can be obtained.

In FIG. 1, the piezoelectric particles 26 in the piezoelectric layer 12 are irregularly dispersed in the matrix 24, but the present invention is not limited thereto.

That is, it is preferable that the piezoelectric particles 26 in the piezoelectric layer 12 may be regularly dispersed in the matrix 24 as long as the piezoelectric particles 26 are uniformly dispersed therein.

In addition, the particle diameter of the piezoelectric particles 26 may or may not be uniform.

In the piezoelectric film 10, a ratio between an amount of the matrix 24 and an amount of the piezoelectric particles 26 in the piezoelectric layer 12 is not limited, and may be appropriately set according to the size and the thickness of the piezoelectric film 10 in the plane direction, the applications of the piezoelectric film 10, the characteristics required for the piezoelectric film 10, and the like.

A volume fraction of the piezoelectric particles 26 in the piezoelectric layer 12 is preferably 30% to 80%, more preferably 50% or more, and still more preferably 50% to 80%.

By setting the ratio between the amount of the matrix 24 and the amount of the piezoelectric particles 26 to be within the above-described range, preferred results in terms of achieving both of excellent piezoelectric characteristics and flexibility can be obtained.

A thickness of the piezoelectric layer 12 in the piezoelectric film 10 is not particularly limited, and may be appropriately set according to the applications of the piezoelectric film 10, the characteristics required for the piezoelectric film 10, and the like.

It is advantageous that the thickness of the piezoelectric layer 12 increases large in terms of stiffness such as the strength of rigidity of a so-called sheet-like material, but the voltage (potential difference) required to stretch and contract the piezoelectric film 10 increases by the same amount.

The thickness of the piezoelectric layer 12 is preferably 8 to 300 μm, more preferably 8 to 200 μm, still more preferably 10 to 150 μm, and particularly preferably 15 to 100 μm.

By setting the thickness of the piezoelectric layer 12 to be within the above-described ranges, preferred results in terms of achieving both ensuring of the rigidity and moderate elasticity can be obtained.

It is preferable that the piezoelectric layer 12, that is, the piezoelectric film 10 is subjected to a polarization treatment (poling) in a thickness direction. The polarization treatment will be described later in detail.

As shown in FIG. 1, the piezoelectric film 10 of the illustrated example has a configuration in which the first electrode layer 14 is provided on one surface of the piezoelectric layer 12, the first protective layer 17 is provided on a surface thereof, the second electrode layer 16 is provided on the other surface of the piezoelectric layer 12, and the second protective layer 19 is provided on a surface thereof.

Here, the first electrode layer 14 and the second electrode layer 16 form an electrode pair. That is, the piezoelectric film 10 has a configuration in which both surfaces of the piezoelectric layer 12 are sandwiched between the electrode pair, that is, the first electrode layer 14 and the second electrode layer 16, and this laminate is sandwiched between the first protective layer 17 and the second protective layer 19.

In such a piezoelectric film 10, a region sandwiched between the first electrode layer 14 and the second electrode layer 16 stretches and contracts according to an applied voltage.

In addition, as described above, the first protective layer 17 and the second protective layer 19 each consist of the resin substrate and the inorganic layer.

In the piezoelectric film 10, the first resin substrate 18 and the second resin substrate 20 support the first inorganic layer 28 and the second inorganic layer 30, respectively. In addition, the first resin substrate 18 and the second resin substrate 20 each have a function of coating the first electrode layer 14 and the second electrode layer 16 and imparting moderate rigidity and mechanical strength to the piezoelectric layer 12. That is, the piezoelectric layer 12 consisting of the matrix 24 and the piezoelectric particles 26 in the piezoelectric film 10 exhibits extremely excellent flexibility under bending deformation at a slow vibration, but may have insufficient rigidity or mechanical strength depending on the applications. As a compensation for this, the piezoelectric film 10 is provided with the first resin substrate 18 and the second resin substrate 20.

The first resin substrate 18 and the second resin substrate 20 are not limited and various sheet-like materials can be used, and suitable examples thereof include various resin films.

Among these, from the viewpoint of excellent mechanical characteristics and heat resistance, a resin film consisting of polyethylene terephthalate (PET), polypropylene (PP), polystyrene (PS), polycarbonate (PC), polyphenylene sulfite (PPS), polymethylmethacrylate (PMMA), polyetherimide (PEI), polyimide (PI), polyethylene naphthalate (PEN), triacetyl cellulose (TAC), a cyclic olefin-based resin, and the like is suitably used.

Thicknesses of the first resin substrate 18 and the second resin substrate 20 are also not limited. In addition, the thicknesses of the first resin substrate 18 and the second resin substrate 20 are basically the same as each other, but may be different from each other.

Here, in a case where the rigidity of the first resin substrate 18 and the second resin substrate 20 is extremely high, not only is the stretch and contraction of the piezoelectric layer 12 constrained, but also the flexibility is impaired. Therefore, it is advantageous that the thicknesses of the first resin substrate 18 and the second resin substrate 20 decrease except for the case where the mechanical strength or favorable handleability as a sheet-like material is required.

In a case where the thicknesses of the first resin substrate 18 and the second resin substrate 20 in the piezoelectric film 10 are two times or less the thickness of the piezoelectric layer 12, preferred results in terms of achieving both ensuring of the rigidity and moderate elasticity can be obtained.

For example, in a case where the thickness of the piezoelectric layer 12 is 50 μm and the first resin substrate 18 and the second resin substrate 20 consist of PET, the thicknesses of the first resin substrate 18 and the second resin substrate 20 are preferably 100 μm or less, more preferably 50 μm or less, and still more preferably 25 μm or less.

The first inorganic layer 28 and the second inorganic layer 30 are formed on the first resin substrate 18 and the second resin substrate 20, respectively.

In the present invention, the first inorganic layer 28 and the second inorganic layer 30 are layers consisting of an inorganic compound, and are layers which impart the water vapor barrier properties.

Materials of the first inorganic layer 28 and the second inorganic layer 30 are not limited, and various layers consisting of an inorganic compound which exhibits gas barrier properties can be used.

Examples thereof include films consisting of inorganic compounds of metal oxides such as aluminum oxide, magnesium oxide, tantalum oxide, zirconium oxide, titanium oxide, and indium tin oxide (ITO); metal nitrides such as aluminum nitride; metal carbides such as aluminum carbide; silicon oxides such as silicon oxide, silicon oxynitride, silicon oxycarbide, and silicon oxynitride carbide; silicon nitrides such as silicon nitride and silicon nitride carbide; silicon carbides such as silicon carbide; hydrides of these compounds; mixtures of two or more of these compounds; or hydrogen-containing substances of these compounds. In addition, a mixture of two or more of the above-described substances can be used.

In particular, from the viewpoint that excellent water vapor barrier properties can be exhibited, metal oxides and nitrides, specifically, silicon nitride, silicon oxide, silicon oxynitride, aluminum oxide, or a mixture of two or more of these compounds are suitably used. Among these, in particular, silicon nitride and a mixture containing silicon nitride are suitably used because they have excellent water vapor barrier properties and high elasticity.

The inorganic layer may be formed by a known vapor phase film forming method such as a capacitively coupled plasma chemical vapor deposition (CCP-CVD) method, an inductively coupled plasma chemical vapor deposition (ICP-CVD) method, sputtering, and vacuum vapor deposition, depending on the forming material of the inorganic layer. From the viewpoint that the inorganic layer is easily formed into an amorphous structure described later, the method of forming the inorganic layer is preferably CVD.

The film thickness of the inorganic layer may be appropriately determined depending on the material such that the inorganic layer can exhibit the target gas barrier properties and the thickness which does not inhibit the vibration of the piezoelectric film. According to the studies by the present inventor, the thickness of the inorganic layer is preferably 100 nm or less, more preferably 10 nm to 50 nm, and particularly preferably 10 nm to 30 nm.

In a case where the thickness of the inorganic layer is 10 nm or more, an inorganic layer which stably exhibits sufficient gas barrier performance can be formed. In addition, in a case where the inorganic layer is excessively thick, the vibration of the piezoelectric film may be inhibited, and breakage, cracks, peeling, and the like may occur. However, by setting the thickness of the inorganic layer to be 100 nm or less, the inhibition of the vibration of the piezoelectric film can be suppressed, and the occurrence of breakage and the like can be prevented.

The thicknesses of the first inorganic layer 28 and the second inorganic layer 30 may be the same or different from each other. In addition, the materials of the first inorganic layer 28 and the second inorganic layer 30 may be the same or different from each other. In addition, the inorganic layer preferably has an amorphous structure. In a case where the inorganic layer has a polycrystalline structure, since the crystal grain boundary is formed, the water molecules are likely to pass through the crystal grain boundary, and there is a concern that high water vapor barrier properties cannot be obtained. On the other hand, in a case where the inorganic layer has an amorphous structure, since the crystal grain boundary is not formed, it is difficult for the water molecules to pass through the crystal grain boundary, and higher water vapor barrier properties can be obtained.

In a crystal structure analysis of the inorganic layer using an X-ray diffractometer, it is possible to determine whether or not the inorganic layer has an amorphous structure by the presence or absence of a peak derived from the crystal structure of the inorganic layer.

In addition, the inorganic layer is preferably an insulator.

In a case where the inorganic layer is disposed to be in contact with the electrode layer as in the configuration shown in FIG. 1, the inorganic layer acts as an electrode together with the electrode layer in a case where the inorganic layer is a conductor. However, the inorganic layer as a conductor is transformed such as being oxidized in a case of being in contact with water, and thus there is a concern that the resistance is changed. Therefore, there is a concern that the piezoelectric characteristics of the piezoelectric film may change depending on the environment.

On the contrary, in a case where the inorganic layer is an insulator, even in the configuration in which the inorganic layer is disposed to be in contact with the electrode layer, since the inorganic layer does not act as an electrode, it is possible to prevent the piezoelectric characteristics of the piezoelectric film from changing depending on the environment.

In addition, in the example shown in FIG. 1, the protective layer has the configuration consisting of the resin substrate and the inorganic layer, but the present invention is not limited thereto. For example, an organic layer which serves as an underlayer of the inorganic layer may be provided between the resin substrate and the inorganic layer. In a case of including the organic layer, the surface of the inorganic layer to be formed can be smoothed, and the water vapor barrier properties of the inorganic layer can be further improved. In addition, a configuration in which an organic layer which protects the inorganic layer is provided on the surface of the inorganic layer may be adopted.

A material of the organic layer is not limited, and a known organic compound can be used.

Specific examples thereof include films of thermoplastic resins such as polyester, (meth)acrylic resin, methacrylic acid-maleic acid copolymer, polystyrene, transparent fluororesin, polyimide, fluorinated polyimide, polyamide, polyamideimide, polyetherimide, cellulose acylate, polyurethane, polyetheretherketone, polycarbonate, alicyclic polyolefin, polyarylate, polyethersulfone, polysulfone, fluorene ring-modified polycarbonate, alicyclic-modified polycarbonate, fluorene ring-modified polyester, and acrylic compound; and organosilicon compounds such as polysiloxane. These compounds may be used in combination. Among these, a radically curable compound and/or a cationically curable compound having an ether group in a functional group is more preferable. In particular, it is more preferable to use an acrylic resin or a methacrylic resin having a polymer of a monomer or an oligomer of an acrylate and/or a methacrylate as a main component. The main component refers to a component having the largest content mass ratio among contained components.

Such an organic layer may be formed (formed into a film) by a known method of forming a layer consisting of an organic compound, depending on the organic layer to be formed. Examples thereof include a coating method and flash vapor deposition.

In addition, in the example shown in FIG. 1, the protective layer has the configuration in which one inorganic layer is provided, but the present invention is not limited thereto, and the protective layer may have a configuration in which two or more inorganic layers are provided. In addition, the inorganic layer and the organic layer which serves as an underlayer of the inorganic layer may have a configuration in which two or more sets of a combination thereof are provided.

In the piezoelectric film 10, the first electrode layer 14 is formed between the piezoelectric layer 12 and the first protective layer 17, and the second electrode layer 16 is formed between the piezoelectric layer 12 and the second protective layer 19. The electrode layer may be formed on the inorganic layer side of the protective layer as in the example shown in FIG. 1, or may be formed on the resin substrate side of the protective layer as in the example shown in FIG. 2.

The first electrode layer 14 and the second electrode layer 16 are provided to apply a voltage to the piezoelectric layer 12 (piezoelectric film 10).

In the present invention, a forming material of the first electrode layer 14 and the second electrode layer 16 is not limited, and various conductors can be used. Specific examples thereof include metals such as carbon, palladium, iron, tin, aluminum, nickel, platinum, gold, silver, copper, titanium, chromium, and molybdenum, alloys thereof, laminates and composites of these metals and alloys, and indium tin oxide. Among these, copper, aluminum, gold, silver, platinum, or indium tin oxide is suitable as the first electrode layer 14 and the second electrode layer 16.

In addition, a method of forming the first electrode layer 14 and the second electrode layer 16 is not limited, and a known method can be used. Examples thereof include film formation by a vapor-phase deposition method (vacuum film forming method) such as vacuum vapor deposition and sputtering, film formation by plating, and a method of bonding a foil formed of the materials described above.

Among these, particularly from the reason that the flexibility of the piezoelectric film 10 can be ensured, a thin film made of copper, aluminum, or the like, which is formed by vacuum vapor deposition, is suitably used as the first electrode layer 14 and the second electrode layer 16. Among these, a thin film made of copper, which is formed by vacuum vapor deposition, is particularly suitably used.

Thicknesses of the first electrode layer 14 and the second electrode layer 16 are not limited. In addition, the thicknesses of the first electrode layer 14 and the second electrode layer 16 are basically the same as each other, but may be different from each other.

Here, same as the first resin substrate 18 and the second resin substrate 20 described above, in a case where the rigidity of the first electrode layer 14 and the second electrode layer 16 is extremely high, not only the stretch and contraction of the piezoelectric layer 12 is constrained, but also the flexibility is impaired. Therefore, it is advantageous that the thicknesses of the first electrode layer 14 and the second electrode layer 16 decrease in a case where electric resistance is not extremely high.

In the piezoelectric film 10, from the viewpoint that the flexibility is not considerably impaired, it is suitable that a product of the thickness and the Young's modulus of the first electrode layer 14 and the second electrode layer 16 is less than a product of the thickness and the Young's modulus of the first resin substrate 18 and the second resin substrate 20.

For example, in a combination in which the first resin substrate 18 and the second resin substrate 20 consist of PET (Young's modulus: approximately 6.2 GPa) and the first electrode layer 14 and the second electrode layer 16 consist of copper (Young's modulus: approximately 130 GPa), in a case where the thicknesses of the first resin substrate 18 and the second resin substrate 20 are assumed to be 25 μm, the thicknesses of the first electrode layer 14 and the second electrode layer 16 are preferably 1.2 μm or less, more preferably 0.3 μm or less, and still more preferably 0.1 μm or less.

As described above, the piezoelectric film 10 has a configuration in which the piezoelectric layer 12 containing the piezoelectric particles 26 in the matrix 24 containing the polymer material is sandwiched between the first electrode layer 14 and the second electrode layer 16, and this laminate is sandwiched between the first protective layer 17 and the second protective layer 19.

In the piezoelectric film 10 according to the embodiment of the present invention, it is preferable that the maximal value of the loss tangent (tan δ) at a frequency of 1 Hz according to the dynamic viscoelasticity measurement is present at normal temperature, and it is more preferable that the maximal value at which the loss tangent is 0.1 or more is present at normal temperature.

In this manner, even in a case where the piezoelectric film 10 is subjected to large bending deformation at a relatively slow vibration of less than or equal to a few Hz from the outside, since the strain energy can be effectively diffused to the outside as heat, occurrence of cracks at the interface between the polymer matrix and the piezoelectric particles can be prevented.

In addition, in the piezoelectric film 10 according to the embodiment of the present invention, it is preferable that the storage elastic modulus (E′) at a frequency of 1 Hz according to the dynamic viscoelasticity measurement is 10 to 30 GPa at 0° C. and 1 to 10 GPa at 50° C.

In such a manner, the piezoelectric film 10 may have large frequency dispersion in the storage elastic modulus (E′) at normal temperature. That is, the piezoelectric film 10 can exhibit a behavior of being rigid with respect to the vibration of 20 Hz to 20 kHz and being flexible with respect to the vibration of less than or equal to a few Hz.

In addition, in the piezoelectric film 10 according to the embodiment of the present invention, it is preferable that a product of the thickness and the storage elastic modulus (E′) at a frequency of 1 Hz according to the dynamic viscoelasticity measurement is 1.0×10⁶ to 2.0 ×10⁶ N/m at 0° C. and 1.0×10⁵ to 1.0×10⁶ N/m at 50° C. The same applies to the conditions for the piezoelectric layer 12.

In this manner, the piezoelectric film 10 may have moderate rigidity and mechanical strength within a range not impairing the flexibility and the acoustic characteristics.

Furthermore, in the piezoelectric film 10, it is preferable that the loss tangent (Tand) at a frequency of 1 kHz at 25° C. is 0.05 or more in a master curve obtained from the dynamic viscoelasticity measurement. The same applies to the conditions for the piezoelectric layer 12.

In this manner, the frequency of a speaker including the piezoelectric film 10 is smooth as the frequency characteristic thereof, and thus an amount of a change in acoustic quality in a case where the lowest resonance frequency f₀ is changed according to a change in curvature of the speaker can be decreased.

In addition, in the present invention, the storage elastic modulus (Young's modulus) and the loss tangent of the piezoelectric film 10, the piezoelectric layer 12, and the like may be measured by a known method. As an example, the measurement may be performed using a dynamic viscoelasticity measuring device DMS6100 (manufactured by SII Nanotechnology Inc.).

Examples of measurement conditions include conditions with a measurement frequency of 0.1 Hz to 20 Hz (0.1 Hz, 0.2 Hz, 0.5 Hz, 1 Hz, 2 Hz, 5 Hz, 10 Hz, and 20 Hz), a measurement temperature of −50° C. to 150° C., a temperature rising rate of 2ºC/min (in a nitrogen atmosphere), a sample size of 40 mm×10 mm (including the clamped region), and a chuck-to-chuck distance of 20 mm.

Furthermore, the piezoelectric film 10 according to the embodiment of the present invention may further include an electrode lead-out portion which leads out the electrodes from the first electrode layer 14 and the second electrode layer 16, an insulating layer which covers a region where the piezoelectric layer 12 is exposed for preventing a short circuit or the like, or the like in addition to the above-described layers.

A method of leading out the electrodes from the first electrode layer 14 and the second electrode layer 16 is not limited, and various known methods can be used.

Examples thereof include a method of providing portions in the electrode layer and the protective layer, which protrude to the outside of the piezoelectric layer 12 in the plane direction, and leading-out electrodes to the outside from these portions, a method of connecting a conductor such as a copper foil to the first electrode layer 14 and the second electrode layer 16 and leading-out the electrodes to the outside, and a method of forming through-holes in the first resin substrate 18 and the second resin substrate 20 with a laser or the like, filling the through-holes with a conductive material, and leading-out electrodes to the outside.

Examples of a suitable method of leading out the electrodes include the method described in JP2014-209724A and the method described in JP2016-015354A.

The number of electrode lead-out portions is not limited to one, and each electrode layer may have two or more electrode lead-out portions. Particularly, in a case of the configuration in which the electrode lead-out portion is obtained by removing a part of the protective layer and inserting a conductive material into the hole portion, it is preferable that the electrode layer has three or more electrode lead-out portions in order to more reliably ensure the conduction.

In addition, the power supply connected to the piezoelectric film 10 is not limited, and may be a direct-current power supply or an alternating-current power supply. In addition, as the driving voltage, a driving voltage capable of suitably driving the piezoelectric films 10 may be suitably set in accordance with the thickness, forming material, and the like of the piezoelectric layer 12 in the piezoelectric film 10.

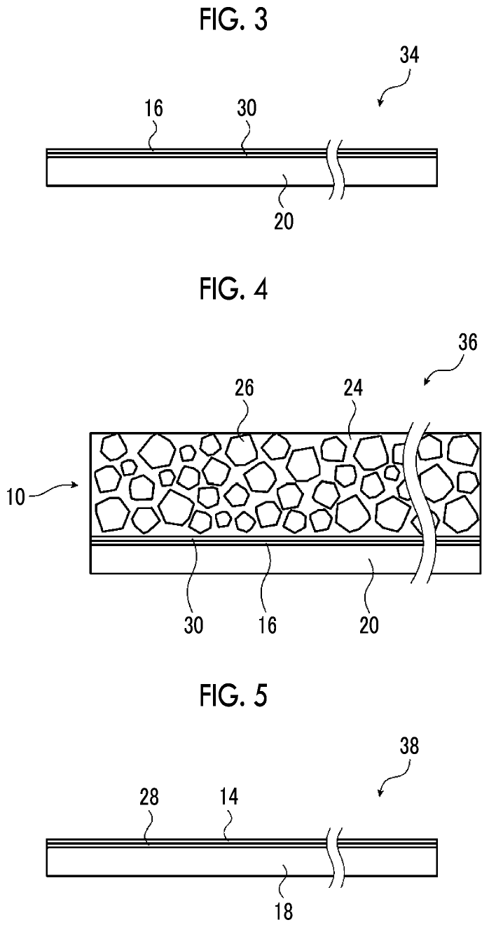

Next, an example of the method of manufacturing the piezoelectric film 10 shown in FIG. 1 will be described with reference to the conceptual views of FIGS. 3 to 6.

First, as shown in FIG. 3, a sheet-like material 34 in which the second inorganic layer 30 and the second electrode layer 16 have been formed on the second resin substrate 20 is prepared. The sheet-like material 34 may be produced by forming a film made of silicon nitride as the second inorganic layer 30 on the surface of the second resin substrate 20 by a CCP-CVD, an ICP-CVD, a sputtering, a vacuum vapor deposition, or the like, and then forming a copper thin film or the like as the second electrode layer 16 on the surface of the second inorganic layer 30 by a vacuum vapor deposition, a sputtering, a plating, or the like.

In a case where the second resin substrate 20 is extremely thin and thus the handleability is degraded, the second resin substrate 20 with a separator (temporary support) may be used as necessary. PET having a thickness of 25 to 100 μm, or the like can be used as the separator. The separator may be removed after thermal compression bonding of the second electrode layer 16 and the second resin substrate 20 and before lamination of any member on the second resin substrate 20.

Meanwhile, the coating material is prepared by dissolving a polymer material such as cyanoethylated PVA in an organic solvent, adding the piezoelectric particles 26 thereto, and stirring the solution for dispersion.

The organic solvent is not limited, and various organic solvents such as dimethylformamide (DMF), methyl ethyl ketone, and cyclohexanone can be used.

In a case where the sheet-like material 34 is prepared and the coating material is prepared, the coating material is cast (applied) onto the second electrode layer 16 of the sheet-like material 34, and the organic solvent is evaporated and dried. In this manner, as shown in FIG. 4, a laminate 36 in which the second inorganic layer 30 is provided on the second resin substrate 20, the second electrode layer 16 is provided on the second inorganic layer 30, and the piezoelectric layer 12 is provided on the second electrode layer 16 is produced.

A casting method for the coating material is not particularly limited, and all known coating methods (coating devices) such as a slide coater and a doctor knife can be used.

In a case where the viscoelastic material is a material that can be heated and melted, such as cyanoethylated PVA, the laminate 36 in which the second electrode layer 16 is provided on the second resin substrate 20 and the piezoelectric layer 12 is formed on the second electrode layer 16 as shown in FIG. 4 may be produced by heating and melting the viscoelastic material to produce a melt obtained by adding the piezoelectric particles 26 to the melt to be dispersed therein, extruding the melt on the sheet-like material 34 shown in FIG. 3 in a sheet shape by carrying out extrusion molding or the like, and cooling the laminate.

As described above, in the piezoelectric film 10, in addition to the viscoelastic material such as cyanoethylated PVA, a dielectric polymer material such as polyvinylidene fluoride may be added to the matrix 24.

In a case where the polymer piezoelectric material is added to the matrix 24, the polymer piezoelectric material to be added to the above-described coating material may be dissolved. Alternatively, the polymer piezoelectric material to be added may be added to the heated and melted viscoelastic material described above so that the polymer piezoelectric material is heated and melted.

After the production of the laminate 36, it is preferable that the surface of the piezoelectric layer 12 is subjected to a calender treatment of pressing the surface using a heating roller or the like for the purpose of flattening the surface of the piezoelectric layer 12, adjusting the thickness of the piezoelectric layer 12, improving the density of the piezoelectric particles 26 in the piezoelectric layer 12, and the like.

The method of performing the calender treatment is not limited, and the calender treatment may be performed by a known method such as pressing the surface with a heating roller described above or a treatment with a pressing machine.

The calender treatment may be performed after a polarization treatment described later. However, in a case where the calender treatment is performed after the polarization treatment is performed, the piezoelectric particles 26 pushed in by the pressure rotate, which may decrease effect of the polarization treatment. In consideration of this point, it is preferable that the calender treatment is performed before the polarization treatment.

After the production of the laminate 36 in which the second inorganic layer 30 is provided on the second resin substrate 20, the second electrode layer 16 is provided on the second inorganic layer 30, and the piezoelectric layer 12 is formed on the second electrode layer 16, it is preferable that a polarization treatment (poling) is performed on the piezoelectric layer 12 after the calender treatment is performed on the piezoelectric layer 12.

A method of performing the polarization treatment on the piezoelectric layer 12 is not limited, and a known method can be used. For example, electric field poling in which a DC electric field is directly applied to a target to be subjected to the polarization treatment is exemplified. In a case of performing the electric field poling, the electric field poling treatment may be performed using the first electrode layer 14 and the second electrode layer 16 by forming the first electrode layer 14 before the polarization treatment.

In addition, in a case where the piezoelectric film 10 according to the embodiment of the present invention is produced, it is preferable that the polarization treatment is performed in the thickness direction instead of the plane direction of the piezoelectric layer 12.

On the other hand, a sheet-like material 38 in which the first inorganic layer 28 is formed on the first resin substrate 18 and the first electrode layer 14 is formed on the first inorganic layer 28 is prepared. The sheet-like material 38 may be produced by forming a film made of silicon nitride as the first inorganic layer 28 on the surface of the first resin substrate 18 by a CCP-CVD, an ICP-CVD, a sputtering, a vacuum vapor deposition, or the like, and then forming a copper thin film or the like as the first electrode layer 14 on the surface of the first inorganic layer 28 by a vacuum vapor deposition, a sputtering, a plating, or the like. That is, the sheet-like material 38 may be the same as the sheet-like material 34 described above.

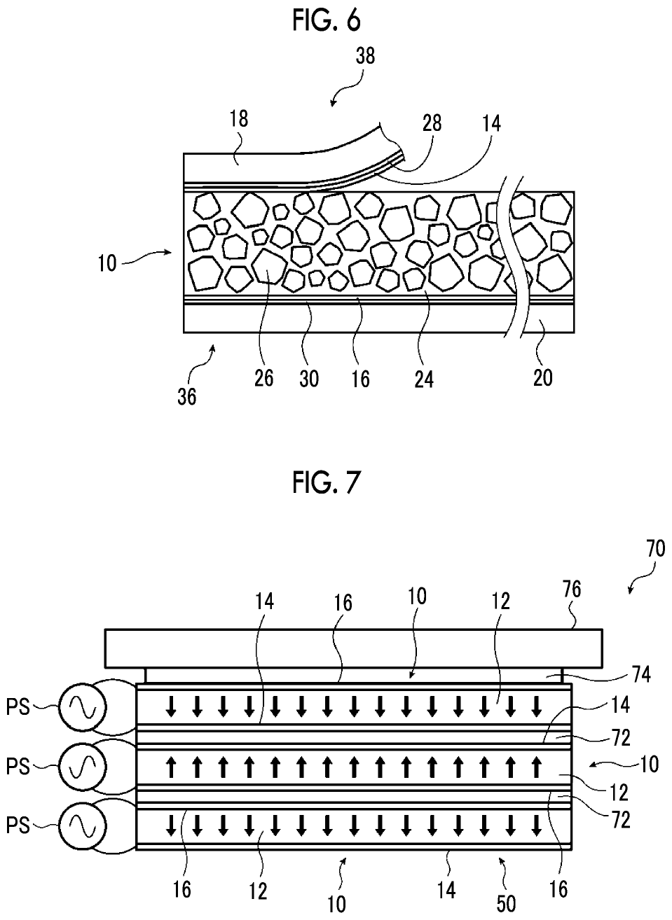

Next, as shown in FIG. 6, the sheet-like material 38 is laminated on the laminate 36 such that the first electrode layer 14 faces the piezoelectric layer 12.

Furthermore, the laminate of the laminate 36 and the sheet-like material 38 is subjected to thermal compression bonding using a heating press device, a heating roller pair, or the like such that the laminate is sandwiched between the second resin substrate 20 and the first resin substrate 18, thereby producing the piezoelectric film 10.

Alternatively, the piezoelectric film 10 may be produced by bonding and preferably further compression-bonding the laminate 36 and the sheet-like material 38 to each other using an adhesive.

Such a piezoelectric film 10 may be produced using the cut sheet-like material 34 and the cut sheet-like material 38, or may be produced using Roll to Roll.

The produced piezoelectric film may be cut into a desired shape according to various applications.

The piezoelectric film 10 to be produced in the above-described manner is polarized in the thickness direction instead of the plane direction, and thus excellent piezoelectric characteristics are obtained even in a case where a stretching treatment is not performed after the polarization treatment. Therefore, the piezoelectric film 10 has no in-plane anisotropy as a piezoelectric characteristic, and stretches and contracts isotropically in all directions in the plane direction in a case where a driving voltage is applied.

Such a piezoelectric film can be used for a piezoelectric speaker that uses the piezoelectric film itself as a vibration plate which vibrates. The piezoelectric speaker can also be used as a microphone, a sensor, or the like. Furthermore, the piezoelectric speaker can also be used as a vibration sensor.

In addition, the piezoelectric film can also be used as a so-called exciter which is bonded to a vibration plate and vibrates the vibration plate. In a case where the piezoelectric film is used as the exciter, it is preferable to use a laminated piezoelectric element obtained by laminating the piezoelectric films in order to obtain a higher output.

### [Laminated Piezoelectric Element]

The laminated piezoelectric element according to the embodiment of the present invention is a laminated piezoelectric element formed by laminating a plurality of layers of the above-described piezoelectric films.

FIG. 7 is a plan view schematically showing an example of the laminated piezoelectric element according to the embodiment of the present invention.

A laminated piezoelectric element 50 shown in FIG. 7 is obtained by laminating a plurality of the piezoelectric films 10. In the example shown in FIG. 7, three piezoelectric films 10 are laminated. Adjacent piezoelectric films 10 are bonded to each other by a bonding layer 72. In addition, in the example shown in FIG. 7, the laminated piezoelectric element 50 is bonded to a vibration plate 76 by a bonding layer 74 to form an electroacoustic transducer 70. A power supply PS for applying a driving voltage is connected to each piezoelectric film 10. In the example shown in FIG. 7, a protective layer of each piezoelectric film is not shown. However, as shown in FIG. 1, each piezoelectric film includes a protective layer.

In the electroacoustic transducer 70, by applying a driving voltage to the piezoelectric film 10 of the laminated piezoelectric element 50, the piezoelectric film 10 stretches and contracts in the plane direction, and the laminated piezoelectric element 50 stretches and contracts in the plane direction due to the stretch and contraction of the piezoelectric film 10.

The vibration plate 76 is bent due to the stretch and contraction of the laminated piezoelectric element 50 in the plane direction, and as a result, the vibration plate 76 vibrates in the thickness direction. The vibration plate 76 generates a sound using the vibration in the thickness direction. The vibration plate 76 vibrates according to the magnitude of the driving voltage applied to the piezoelectric film 10 and generates the sound according to the driving voltage applied to the piezoelectric film 10.

That is, the electroacoustic transducer 70 can be used as a speaker which uses the laminated piezoelectric element 50 as an exciter.

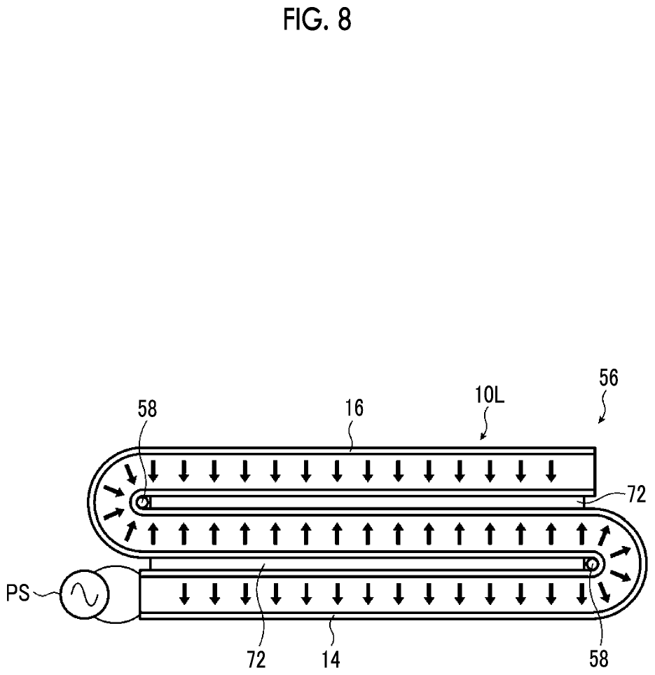

The laminated piezoelectric element 50 shown in FIG. 7 is formed by laminating the piezoelectric films 10 in three layers, but the present invention is not limited thereto. That is, the number of laminated piezoelectric films 10 may be two layers or four or more layers as long as the piezoelectric element is formed by laminating a plurality of layers of the piezoelectric films 10. The same also applies to a laminated piezoelectric element 56 shown in FIG. 8, which will be described later.

In the laminated piezoelectric element 50 shown in FIG. 7, as a preferred aspect, polarization directions of the adjacent piezoelectric films 10 are opposite to each other. Therefore, in the adjacent piezoelectric films 10, the first electrode layers 14 face each other and the second electrode layers 16 face each other. Therefore, the power supply PS constantly supplies power of the same polarity to the facing electrodes regardless of whether the power supply PS is an alternating-current power supply or a direct-current power supply. For example, in the laminated piezoelectric element 50 shown in FIG. 7, power of the same polarity is constantly supplied to the second electrode layer 16 of the piezoelectric film 10 which is the lowermost layer in the drawing and to the second electrode layer 16 of the piezoelectric film 10 which is the second layer (middle layer), and power of the same polarity is constantly supplied to the first electrode layer 14 of the piezoelectric film 10 which is the second layer and to the first electrode layer 14 of the piezoelectric film 10 which is the uppermost layer in the drawing. Accordingly, in the laminated piezoelectric element 50, even in a case where the electrodes of the adjacent piezoelectric films 10 come into contact with each other, there is no risk of a short circuit.

In the laminated piezoelectric element 50, the polarization direction of the piezoelectric film 10 may be detected by a d33 meter or the like. Alternatively, the polarization direction of the piezoelectric film 10 may be known from the polarization processing conditions described above.

In the example shown in FIG. 7, the polarization directions of the adjacent piezoelectric films 10 are opposite to each other, but the present invention is not limited thereto, and the polarization directions of the piezoelectric layers 12 may be all the same.

In addition, in the example shown in FIG. 7, a plurality of sheet-like piezoelectric films 10 are laminated, but the present invention is not limited thereto.

FIG. 8 shows another example of the laminated piezoelectric element. Since a laminated piezoelectric element 56 shown in FIG. 8 uses a plurality of the same members as those of the laminated piezoelectric element 50 described above, the same members are denoted by the same reference numerals and the description will be given mainly to different parts.

The laminated piezoelectric element 56 shown in FIG. 8 is formed by lamination of a plurality of piezoelectric films by folding a long piezoelectric film 10L one or more times, preferably a plurality of times in a longitudinal direction. In addition, in the laminated piezoelectric element 56, the piezoelectric film 10L folded and laminated is bonded by the bonding layer 72.

By folding and laminating one long piezoelectric film 10L polarized in the thickness direction, the polarization directions of the piezoelectric film adjacent (facing) in the lamination direction are opposite directions as indicated by the arrows in FIG. 8.

According to the configuration, the laminated piezoelectric element 56 can be configured with only one long piezoelectric film 10L and only one power supply PS for applying the driving voltage, and an electrode may be led out from the piezoelectric film 10L at one place.

Therefore, according to the laminated piezoelectric element 56 shown in FIG. 8, the number of components can be reduced, the configuration can be simplified, the reliability of the piezoelectric element (module) can be improved, and a further reduction in cost can be achieved.

Same as the laminated piezoelectric element 56 shown in FIG. 8, in the laminated piezoelectric element 56 in which the long piezoelectric film 10L is folded, it is preferable that a core rod 58 is brought into contact with the piezoelectric film 10L and inserted into a folded-back portion of the piezoelectric film 10L.

The first electrode layer 14 and the second electrode layer 16 of the piezoelectric film 10L are made of a metal vapor deposition film or the like. In a case where the metal vapor deposition film is bent at an acute angle, cracks and the like are likely to occur, and thus the electrode may be broken. That is, in the laminated piezoelectric element 56 shown in FIG. 8, cracks and the like are likely to occur in the electrode inside a bent portion.

For this, in the laminated piezoelectric element 56 in which the long piezoelectric film 10L is folded, by inserting the core rod 58 into the folded-back portion of the piezoelectric film 10L, the first electrode layer 14 and the second electrode layer 16 are prevented from being bent. Therefore, the occurrence of breakage can be suitably prevented.

Hereinbefore, the piezoelectric film and the laminated piezoelectric element according to the embodiment of the present invention have been described in detail, but the present invention is not limited to the above-described examples, and various improvements or modifications may be made within a range not departing from the scope of the present invention.

### EXAMPLES

Hereinafter, the present invention will be described in more detail with reference to specific examples of the present invention.

### Example 1

A piezoelectric film shown in FIG. 1 was produced by the methods shown in FIGS. 3 to 6.

First, cyanoethylated PVA (CR-V, manufactured by Shin-Etsu Chemical Co., Ltd.) was dissolved in dimethylformamide (DMF) at the following compositional ratio. Thereafter, PZT particles as piezoelectric particles were added to the solution at the following compositional ratio, and the solution was stirred using a propeller mixer (rotation speed: 2000 rpm), thereby preparing a coating material for forming a piezoelectric layer.
PZT Particles: 300 parts by mass
Cyanoethylated PVA: 30 parts by mass
DMF: 70 parts by mass

PZT particles which were obtained by sintering mixed powder, formed by wet-mixing powder of a Pb oxide, a Zr oxide, and a Ti oxide as main components using a ball mill such that the amount of Zr and the amount of Ti respectively reached 0.52 moles and 0.48 moles with respect to 1 mole of Pb, at 800° C. for 5 hours and being subjected to a crushing treatment were used as the PZT particles.

On the other hand, two sheet-like materials obtained by forming a silicon nitride (Si₃N₄) having a thickness of 10 nm on a PET film having a thickness of 4 μm by plasma CVD and further forming a copper thin film having a thickness of 0.1 μm on the silicon nitride film by vacuum vapor deposition were prepared. That is, in the present example, the first electrode layer and the second electrode layer were copper-deposited thin films having a thickness of 0.1 m, the first inorganic layer and the second inorganic layer were silicon nitride layers having a thickness of 10 nm, and the first resin substrate and the second resin substrate were PET films having a thickness of 4 μm. During the formation of the inorganic layers and the electrode layers, a resin substrate having a separator (PET film) having a thickness of 50 μm on a back surface side of the PET film having a thickness of 4 μm was used.

In a case where a water vapor transmission rate of the sheet-like material before forming the electrode layer, that is, the protective layer was measured by a calcium corrosion method, the water vapor transmission rate was 5×10⁵ g/(m²×day).

The copper thin film (second electrode layer) of one sheet-like material was coated with the coating material for forming a piezoelectric layer, which was prepared in advance, using a slide coater. The coating material was applied so that a film thickness of the coating film after drying was 30 μm.

Next, the material obtained by coating the sheet-like material with the coating material was heated and dried on a hot plate at 120° C. to evaporate DMF. In this manner, a laminate in which the second inorganic layer made of silicon nitride was provided on the second resin substrate made of PET, the second electrode layer made of copper was provided on the second inorganic layer, and the piezoelectric layer (polymer-based piezoelectric composite material layer) having a thickness of 30 μm was formed thereon was produced.

The produced piezoelectric layer was subjected to a calender treatment using a heating roller.

Furthermore, the produced piezoelectric layer was subjected to a polarization treatment in the thickness direction.

On the laminate subjected to the polarization treatment, as shown in FIG. 6, a silicon nitride layer was formed on the PET film, and the same sheet-like material obtained by vacuum-depositing a copper thin film on the silicon nitride layer was laminated thereon.

Next, the laminate of the laminate and the sheet-like material was subjected to thermal compression bonding at 120° C. using a laminator device to bond the first electrode layer and the second electrode layer to the piezoelectric layer and sandwich the piezoelectric layer between the first electrode layer and the second electrode layer. Thereafter, the laminate was sandwiched between the first protective layer (the first inorganic layer and the first resin substrate) and the second protective layer (the second inorganic layer and the second resin substrate) to produce a piezoelectric film as shown in FIG. 1. After the lamination, the separator bonded to the PET film as the protective layer was removed.

In a case where a water vapor transmission rate of the produced piezoelectric film was measured by a calcium corrosion method, the water vapor transmission rate was 5×10⁻⁵ g/(m²×day).

In addition, in a case where crystal structure analysis was performed using an X-ray diffractometer (Rint Ultima III manufactured by Rigaku Corporation), it was confirmed that the inorganic layer had an amorphous structure.

### Example 2

A piezoelectric film was produced in the same manner as in Example 1, except that the inorganic layer was formed on a surface of the resin substrate opposite to the electrode layer (see FIG. 2).

In Example 2, the sheet-like material was produced by forming an inorganic layer on a surface of the PET film with a first separator, having a thickness of 4 μm, bonding a second separator to the surface of the inorganic layer, removing the first separator, and then forming the electrode layer on the surface from which the separator had been removed.

In a case where a water vapor transmission rate of the produced piezoelectric film was measured by a calcium corrosion method, the water vapor transmission rate was 5×10⁻⁵ g/(m²×day).

In addition, in a case where crystal structure analysis was performed using an X-ray diffractometer (Rint Ultima III manufactured by Rigaku Corporation), it was confirmed that the inorganic layer had an amorphous structure.

### Comparative Example 1

A piezoelectric film was produced in the same manner as in Example 1, except that the inorganic layer was not provided.

The water vapor transmission rate of the piezoelectric film of Comparative Example 1 was 1×10⁻² g/(m²×day).

### Comparative Example 2

A piezoelectric film was produced in the same manner as in Example 1, except that the inorganic layer was changed to alumina (aluminum oxide). The aluminum oxide film was formed by sputtering.

The water vapor transmission rate of the piezoelectric film of Comparative Example 2 was 5×10⁴ g/(m²×day). In addition, it was confirmed that the inorganic layer had an amorphous structure.

### [Evaluation]

Changes in mechanical properties (Young's modulus) and electrical properties (electrostatic capacitance) of the produced piezoelectric film before and after a storage test were evaluated.

### <Mechanical Properties (Young's Modulus)>

A test piece was obtained by cut out each of the produced piezoelectric films into strips of 1 cm×4 cm. A Young's modulus E′ (GPa) immediately after the cutting and after storage for 6 hours in an atmosphere of 80° C. and 95% RH was measured using a dynamic viscoelasticity tester (SII Nanotechnology DMS6100 viscoelasticity spectrometer). The measurement conditions were as follows.

Measurement temperature range: −20° C. to 100° C.

Temperature rising rate: 2° C./min

Measurement frequency: 0.1 Hz, 0.2 Hz, 0.5 Hz, 1.0 Hz, 2.0 Hz, 5.0 Hz, 10 Hz, and 20 Hz

Measurement mode: tensile measurement

In general, there is a constant relationship between the frequency and the temperature in the dynamic viscoelasticity measurement results based on “time-temperature superposition principle”. For example, a change in temperature could be converted into a change in frequency, and the frequency dispersion of the Young's modulus at a constant temperature could be examined. A curve created at this time is referred to as a master curve. The Young's modulus at a frequency of 1 kHz was obtained from the master curve at 25° C.

From the obtained Young's modulus, a rate of change in the Young's modulus after the storage with respect to the Young's modulus before the storage was calculated.

### <Electrical Properties (Electrostatic Capacitance)>

The electrostatic capacitance was measured as follows immediately after the production and after storage for 6 hours in an atmosphere of 80° C. and 95% RH.

A wiring line was led out from the first electrode layer and the second electrode layer of the piezoelectric film, and the electrostatic capacitance was measured under the following conditions using an LCR meter (ZM2353 manufactured by NF Corporation).

Measurement condition:

Frequency: 1 kHz

Applied voltage: 1 V

From the obtained electrostatic capacitance, a rate of change in the electrostatic capacitance after the storage with respect to the electrostatic capacitance before the storage was calculated.

The results are shown in Table 1.

TABLE 1

| | | | | Piezoelectric film | Evaluation | |
|---|---|---|---|---|---|---|
| | | | | Water vapor | Rate of change | Rate of change |
| | Inorganic layer | | | transmission rate | in electrostatic | in Young's |
| | Disposition | Material | Structure | g/(m² × day) | capacitance | modulus |
| Example 1 | Electrode | Silicon | Amorphous | 5 × 10⁻⁵ | 8% | −5% |
| | side | nitride | | | | |
| Example 2 | Surface | Silicon | Amorphous | 5 × 10⁻⁵ | 10% | −7% |
| | side | nitride | | | | |
| Comparative | — | — | — | 1 × 10⁻² | 55% | −70% |
| Example 1 | | | | | | |
| Comparative | Electrode | Alumina | Amorphous | 5 × 10⁻⁴ | 40% | −42% |
| Example 2 | side | | | | | |

From Table 1, it was found that the piezoelectric films according to the embodiment of the present invention had a smaller change in mechanical properties (Young's modulus) and electrical properties (electrostatic capacitance) as compared with Comparative Examples.

In addition, from the comparison between Example 1 and Example 2, it was found that the inorganic layer was preferably disposed on the electrode side, that is, between the resin substrate and the piezoelectric layer.

From the above results, the effect of the present invention is clear.

The piezoelectric film and laminated piezoelectric element according to the embodiment of the present invention are suitably used as the following, for example: as various sensors such as a sound wave sensor, an ultrasonic wave sensor, a pressure sensor, a tactile sensor, a strain sensor, and a vibration sensor (which are useful particularly for an infrastructure examination such as crack detection and a manufacturing site inspection such as foreign matter contamination detection); acoustic devices such as microphones, pickups, speakers, and exciters (as specific applications, noise cancellers (used for cars, trains, airplanes, robots, and the like), artificial voice bands, buzzers to prevent pests and beasts from invading, furniture, wallpaper, photo, helmet, goggles, headrest, signage, robot, and the like are exemplified); haptics used for application to automobiles, smartphones, smart watches, games, and the like; ultrasonic transducers such as ultrasound probe and hydrophones; actuators used for prevention of attachment of water droplets, transportation, agitation, dispersion, polishing, and the like; damping materials (dampers) used for containers, vehicles, buildings, sports equipment such as skis and rackets; and vibration power generator used for application to roads, floors, mattresses, chairs, shoes, tires, wheels, computer keyboards, and the like.

### EXPLANATION OF REFERENCES

10, 10b, 10L: piezoelectric film
12: piezoelectric layer
14: first electrode layer
16: second electrode layer
17: first protective layer
18: first resin substrate
19: second protective layer
20: second resin substrate
24: matrix
26: piezoelectric particle
28: first inorganic layer
30: second inorganic layer
34, 38: sheet-like material
36: laminate
50, 56: laminated piezoelectric element
58: core rod
70: electroacoustic transducer
72, 74: bonding layer

What is claimed is:

1. A piezoelectric film comprising:
a piezoelectric layer containing piezoelectric particles in a matrix containing a polymer material;
electrode layers provided on both surfaces of the piezoelectric layer; and
a protective layer provided on a surface of the electrode layer opposite to the piezoelectric layer,
wherein the protective layer has a resin substrate and at least one inorganic layer provided on the resin substrate, and
a water vapor transmission rate of the piezoelectric film is 1×10⁻⁴ g/(m²×day) or less.

2. The piezoelectric film according to claim 1,
wherein a water vapor transmission rate of the protective layer is 1×10⁻⁴ g/(m²×day) or less.

3. The piezoelectric film according to claim 1,
wherein the inorganic layer is disposed between the piezoelectric layer and the resin substrate.

4. The piezoelectric film according to claim 1,
wherein the inorganic layer has an amorphous structure.

5. The piezoelectric film according to claim 1,
wherein the inorganic layer is an insulator.

6. The piezoelectric film according to claim 1,
wherein the inorganic layer consists of silicon nitride.

7. The piezoelectric film according to claim 1,
wherein a thickness of the inorganic layer is 100 nm or less.

8. A laminated piezoelectric element obtained by laminating a plurality of layers of the piezoelectric films according to claim 1.

9. The laminated piezoelectric element according to claim 8,
wherein the plurality of layers of the piezoelectric films are laminated by folding the piezoelectric film one or more times.

10. The piezoelectric film according to claim 2,
wherein the inorganic layer is disposed between the piezoelectric layer and the resin substrate.

11. The piezoelectric film according to claim 2,
wherein the inorganic layer has an amorphous structure.

12. The piezoelectric film according to claim 2,
wherein the inorganic layer is an insulator.

13. The piezoelectric film according to claim 2,
wherein the inorganic layer consists of silicon nitride.

14. The piezoelectric film according to claim 2,
wherein a thickness of the inorganic layer is 100 nm or less.

15. A laminated piezoelectric element obtained by laminating a plurality of layers of the piezoelectric films according to claim 2.

16. The laminated piezoelectric element according to claim 15,
wherein the plurality of layers of the piezoelectric films are laminated by folding the piezoelectric film one or more times.

17. The piezoelectric film according to claim 3,
wherein the inorganic layer has an amorphous structure.

18. The piezoelectric film according to claim 3,
wherein the inorganic layer is an insulator.

19. The piezoelectric film according to claim 3,
wherein the inorganic layer consists of silicon nitride.

20. The piezoelectric film according to claim 3,
wherein a thickness of the inorganic layer is 100 nm or less.
